(19) United States
(12) Patent Application Publication
(10) Pub. No.: US 2024/0222257 A1
(43) Pub. Date: Jul. 4, 2024

(54) GLASS SUBSTRATE DEVICE WITH PLATED THROUGH HOLES

(71) Applicant: Intel Corporation, Santa Clara, CA (US)

(72) Inventors: Bohan Shan, Chandler, AZ (US); Haobo Chen, Chandler, AZ (US); Srinivas Venkata Ramanuja Pietambaram, Chandler, AZ (US); Hongxia Feng, Chandler, AZ (US); Gang Duan, Chandler, AZ (US); Xiaoying Guo, Chandler, AZ (US); Yiqun Bai, Chandler, AZ (US); Dingying Xu, Chandler, AZ (US); Bai Nie, Chandler, AZ (US); Kyle Jordan Arrington, Gilbert, AZ (US); Ziyin Lin, Chandler, AZ (US); Rahul N. Manepalli, Chandler, AZ (US); Brandon C. Marin, Gilbert, AZ (US); Jeremy D. Ecton, Gilbert, AZ (US)

(21) Appl. No.: 18/089,801

(22) Filed: Dec. 28, 2022

(51) Int. Cl. H01L 23/498; H01L 21/48; H01L 23/538

(52) U.S. Cl. CPC H01L 23/49894; H01L 21/481; H01L 21/486; H01L 23/49827; H01L 23/5384; H01L 23/15

(57) ABSTRACT

A substrate for an electronic system includes a glass core layer. The glass core layer includes a first surface and a second surface opposite the first surface; and at least one through-glass via (TGV) extending through the glass core layer from the first surface to the second surface. The TGV includes an opening filled with an electrically conductive material; and a via liner including a sidewall material disposed on a sidewall of the opening between the glass of the glass core layer and the electrically conductive material, wherein the sidewall material includes carbon.

### TECHNICAL FIELD

Embodiments pertain to packaging of integrated circuits (ICs). Some embodiments relate to interconnection of ICs using an IC package substrate that includes a glass core.

### BACKGROUND

Electronic systems often include integrated circuits (ICs) that are connected to a subassembly such as a substrate of an electronic package that include many ICs. As electronic system designs become more complex, it is a challenge to route the desired interconnection of the ICs of the systems. Additionally, the signals communicated using the routing are becoming higher frequency, which leads to a need for dense routing with high bandwidth and without crosstalk.

### BRIEF DESCRIPTION OF THE DRAWINGS

FIG. 1 is an illustration of a cross section side view of an example of a substrate for an electronic system in accordance with some embodiments;

FIG. 2 is an illustration of a cross section side view of another example of a substrate for an electronic system in accordance with some embodiments;

FIGS. 3A-3E illustrate a flow diagram of an example of a method of manufacture of a glass core layer in accordance with some embodiments;

FIG. 4 is an illustration of a cross section side view of an example of an electronic system in accordance with some embodiments;

FIG. 5 is an illustration of a cross section side view of another example of an electronic system in accordance with some embodiments;

FIG. 6 illustrates a system level diagram in accordance with some embodiments.

### DETAILED DESCRIPTION

The following description and the drawings sufficiently illustrate specific embodiments to enable those skilled in the art to practice them. Other embodiments may incorporate structural, logical, electrical, process, and other changes. Portions and features of some embodiments may be included in, or substituted for, those of other embodiments. Embodiments set forth in the claims encompass all available equivalents of those claims.

To meet the demand for increased functional complexity in smaller devices, semiconductor substrate packaging can include glass cores. Glass cores enable transmission of high frequency signals within the package. This is particularly useful in an electronic system that includes central processing unit (CPU) tiles and high-bandwidth memory tiles in a disaggregated CPU architecture. Glass cores also allow improved coplanarity and stiffness over cores made from organic materials.

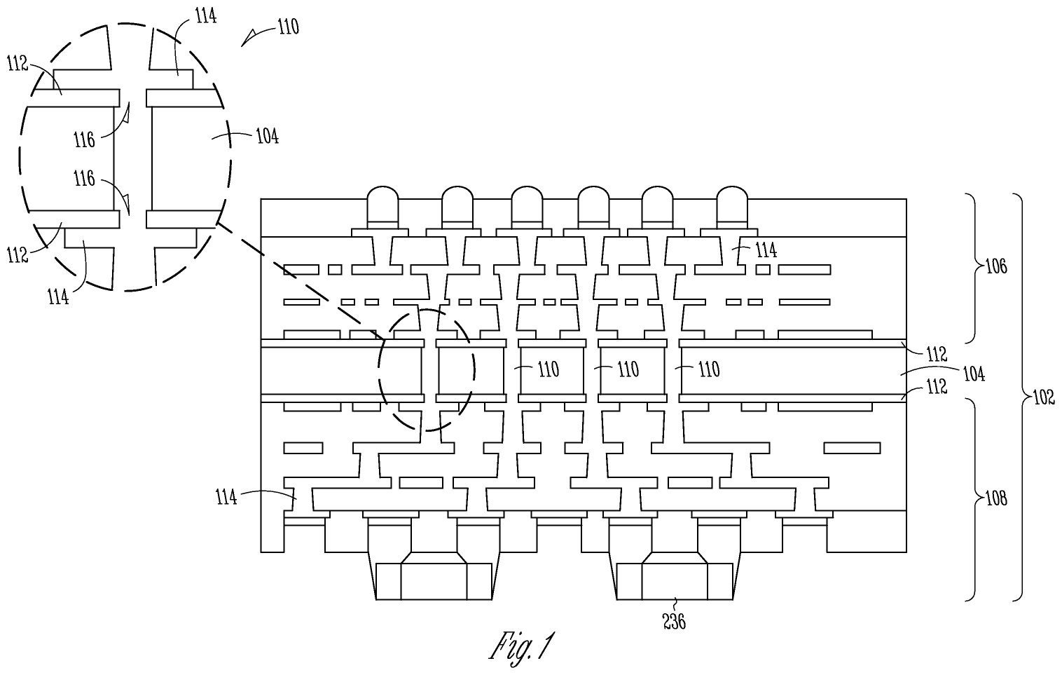

FIG. 1 is an illustration of an electronic package substrate for an electronic system. The substrate 102 includes a glass core layer 104, a front-side buildup layer 106 on the top surface of the glass core layer 104, and a backside buildup layer 108 on the bottom surface of the glass core layer 104. The buildup layers 106, 108 include electrically conductive interconnect 114 (e.g., vias and traces) in layers of a dielectric material.

The glass core layer 104 includes through glass vias (TGVs) 110 that extend through the glass core layer to provide electrical connection between the interconnect of the front and backside buildup layers 106, 108. The TGVs 110 and the electrically conductive interconnect of the buildup layers can include a metal (e.g., copper). The mismatch in the coefficient of thermal expansion (CTE) between the metal and the glass of the glass core layer 104 can result in stresses that cause cracking of the glass.

The substrate 102 includes a buffer layer 112 to address the stress between the buildup layers 106, 108 and glass core layer 104, but adding the buffer layer 112 can include challenges. FIG. 1 includes a blowup view of a TGV 110. The buffer layer 112 includes openings 116 to connect the TGV 110 and the conductive interconnect 114 of the buildup layers 106, 108. The blowup view shows that the openings 116 are smaller than the width of the TGV 110. The opening 116 is small due to overlay accuracy in aligning the features. This can cause small via reliability concerns. Also, the buffer layer 112 may not totally resolve the difference in CTE between glass and metal such as copper, and the buffer layer does not address the glass/metal interface within the TGV 110.

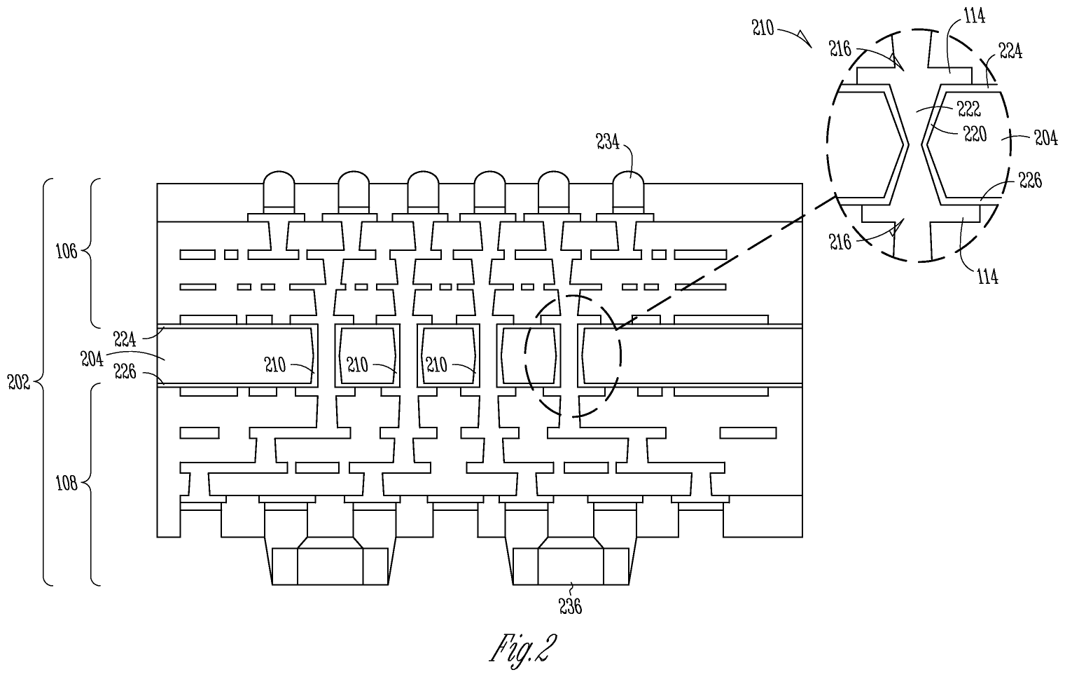

FIG. 2 is an illustration of another electronic package substrate for an electronic system. The substrate 202 includes a glass core layer 204, a front-side buildup layer 106 on the top surface of the glass core layer 204, and a backside buildup layer 108 on the bottom surface of the glass core layer 204. The glass core layer 204 may include a silicate-based glass (e.g., lithium-silicate, borosilicate, aluminum silicate, etc.). In variations, the glass of the glass core layer 204 is a lower quality glass (e.g., glass made with soda lime), or a higher quality glass (e.g., quartz glass made with fused silica). The glass core layer 204 includes TGVs 210.

FIG. 2 shows a blowup view of a TGV 210. The TGV 210 includes a via opening through the glass core layer 204 that includes a plug 222 of an electrically conductive material such as metal (e.g., copper). The TGV 210 includes a via liner 220 between the glass of the glass core layer 204 and the plug 222. The via liner 220 includes a sidewall material disposed on the sidewall or sidewalls of the via opening. The sidewall material provides a stress relieving layer that can prevent cracking of the glass during processes that stress the glass. The buffer material has low modulus (e.g., 70-690 MegaPascals, or 70-690 MPa). In various implementations intended to be non-limiting, the sidewall material is an organic material comprising carbon, such as parylene for example.

The material disposed on the sidewall is also disposed on the top surface of the glass core layer 204 to form a top surface buffer layer 224 and on the bottom surface of the glass core layer 204 to form a bottom surface buffer layer 226. The surface buffer layers 224, 226 are arranged between the glass core layer 204 and the buildup layers 106, 108. The low modulus of the via liner 220, top surface buffer layer 224, and bottom surface buffer layer 226 resolves the issue of stress due to interfaces of glass and metal from the conductive interconnect 114 of the buildup layers 106, 108, and the glass and metal interface due to the plug 222 of the TGV 210. Also, the openings 216 of the surface buffer layers are substantially the same width of the TGV 210 below the top surface buffer layer and above the bottom surface buffer layer. Thus, the TGV 210 of FIG. 2 resolves the issue of small via openings.

Integrated circuit (IC) die can be attached to the solder bumps 234 on the top surface of the front-side buildup layer 106. Discrete passive components 236 can be attached to the backside buildup layer 108 to provide backside power connections for the electronic system.

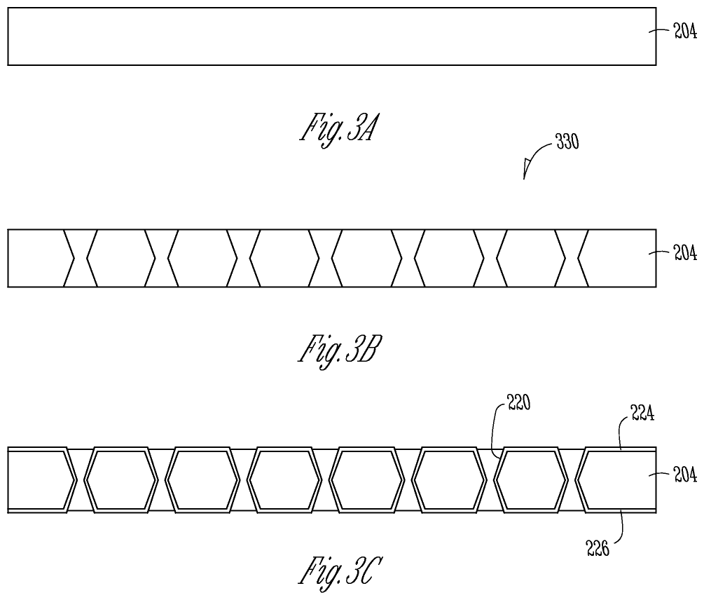

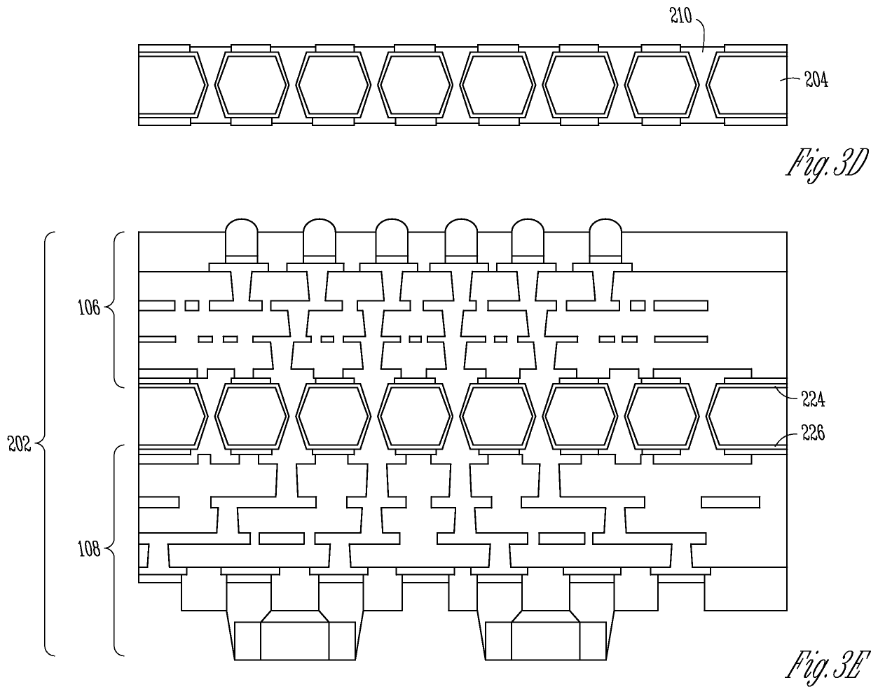

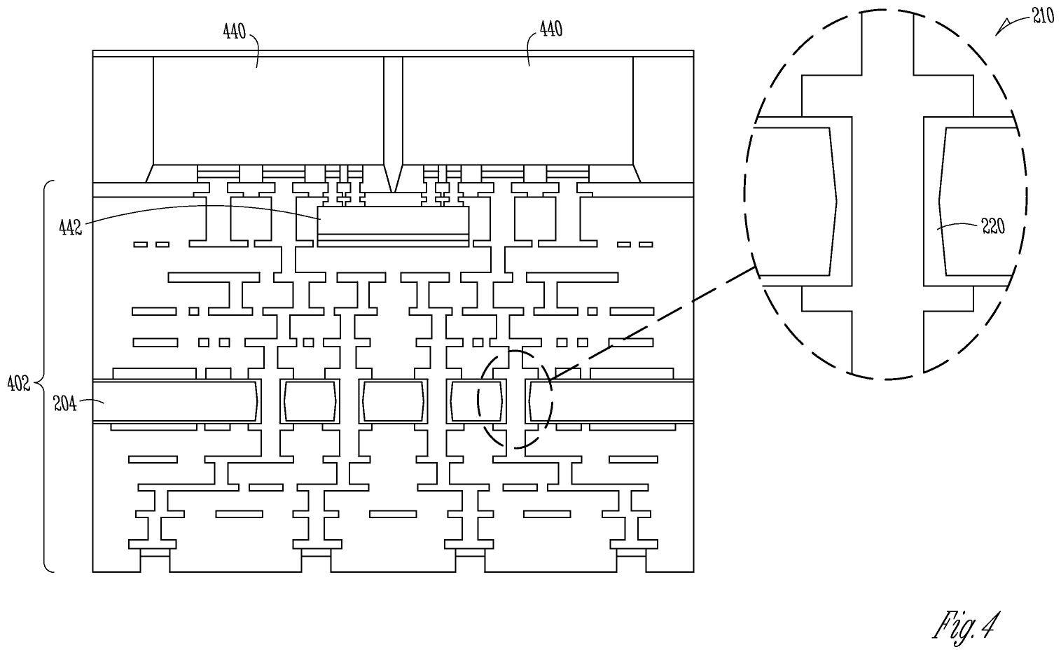

FIGS. 3A-3E illustrate a flow diagram of an example of a method of manufacture of making TGVs for a substrate, such as the substrate 202 of FIG. 2. FIG. 3A is a side view of a glass panel that will be the glass core layer 204 of the substrate 202. In FIG. 3B, openings 330 for TGVs are formed in the glass core layer 204. In some examples, first cavities are formed on a first side of the glass core layer 204. The first cavities are the first portion of the openings 330 for the TGVs. The cavities can be formed by laser drilling. In some examples the cavities are formed by drilling and a wet etching process. Second cavities are formed on the opposite side of the glass core layer to complete the openings 330 for the TGVs. The sidewalls of the cavities can taper towards the point where the cavities drilled from opposite sides meet.

In FIG. 3C, a stress relieving buffer material is deposited on the surfaces of the glass core layer 204 and the sidewall or sidewalls of the openings 330 of the glass core layer 204. The buffer material may be uniformly deposited on the surfaces and sidewalls using a chemical vapor deposition (CVD) process, physical vapor deposition (PVD) process, atomic layer deposition (ALD) process, or other process that can form a uniform layer deposition. The buffer material forms a via liner 220, a top surface buffer layer 224 for the glass core, and a bottom surface buffer layer 226.

In FIG. 3D, the openings are filled with a metal to form the TGVs 210. In some examples, the metal is copper. A titanium/copper seed may be deposited over the coated sidewalls followed by a photoresist assisted copper plating to form the TGVs 210. In FIG. 3E, buildup layers 106, 108 are formed on the top and bottom surface buffer layers 224, 226. The TGVs 210 are connected to the interconnect of the buildup layers 106, 108.

The buffer material should interact well with the glass and the metal selected for the TGVs and the conductive interconnect. The buffer material should have low modulus to relieve stress at the glass/metal interfaces during processing. The buffer material should also be able to be uniformly deposited on the surfaces and the openings. As explained previously herein, parylene satisfies the requirements for the buffer material, but other material with low modulus can be used. Because of the method of lining and metalizing the TGVs, the need for a smaller opening in the surface buffer layers to contact the TGVs is eliminated, and the width of the opening in the surface buffer layers is the width of the buffer-lined TGV.

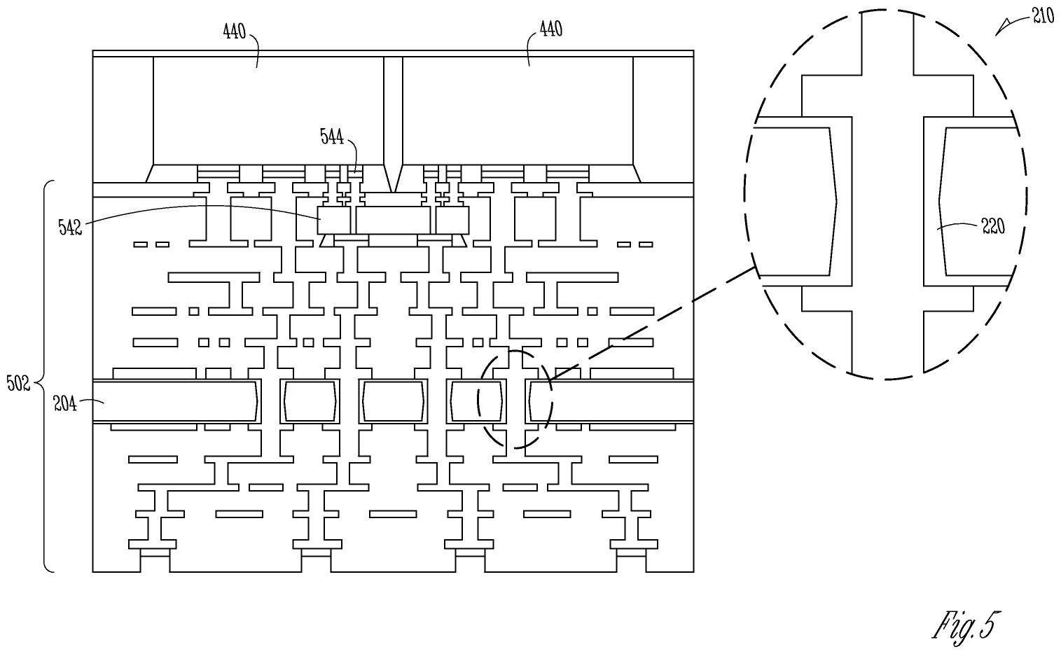

FIG. 4 is an illustration of a cross section side view of an example of an electronic system. The system includes two IC dies 440 mounted on a substrate 402. The IC dies may be compute dies (e.g., a central processing unit (CPU), graphics processing unit (GPU), or other processing unit (XPU)). The substrate 402 has a glass core layer 204 that includes TGVs 210 with stress relieving via liners 220.

The substrate 402 has a front-side buildup layer that includes a multi-die interconnect bridge (MIB) 442 embedded in the buildup layer. The MIB 442 is a small component with features created using a lithography process. The MIB 442 can include a silicon material or an organic material. The MIB 442 includes electrically conductive interconnect with features having a finer pitch and higher density than the conductive interconnect of the buildup layer. The MIB 442 can provide very high density die-to-die connections to the IC dies 440 where it is needed in the substrate 402.

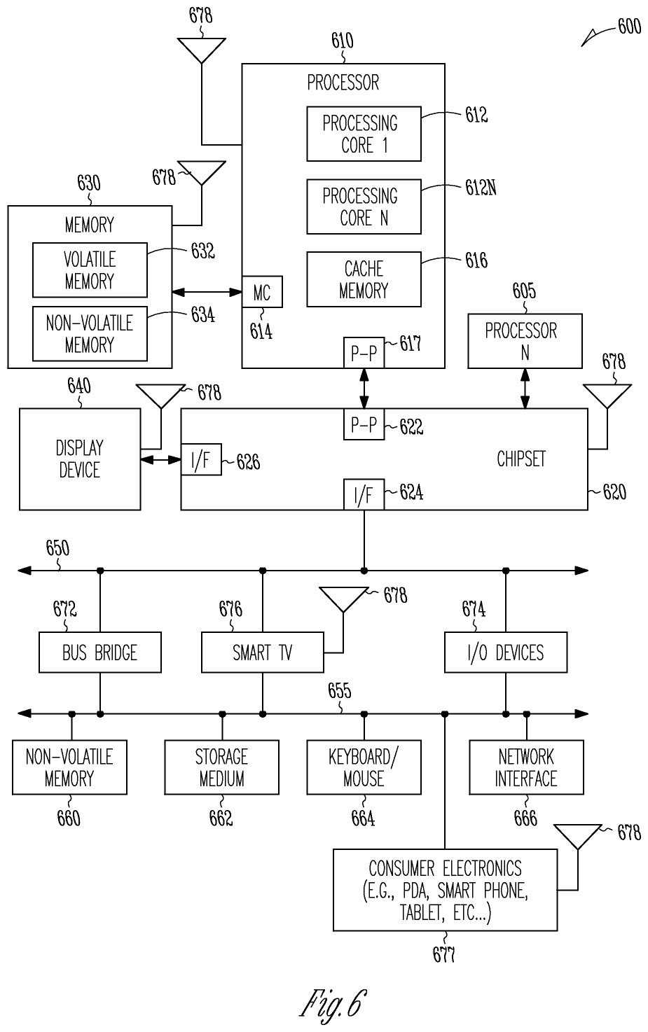

FIG. 5 is an illustration of a cross section side view of another example of an electronic system. The system includes the two IC dies 440 mounted on a substrate 502. The substrate 502 again has a glass core layer 204 that includes TGVs 210 with stress relieving via liners 220. The substrate 502 has a front-side buildup layer that includes a MIB 542 embedded in the buildup layer. The MIB 542 in FIG. 5 includes interconnect connections on both the top side and bottom side of the MIB 542. The IC dies 440 can be bonded to the substrate 502 using bonding pads 544. The conductive interconnect of the buildup layer provides electrical continuity between the TGVs, the MIB 542, and the bonding pads 544.

The methods, devices, and systems described herein provide interconnect that can accommodate high frequency signals while providing very dense signal routing. The interfaces between glass and metal include a stress relieving buffer material to reduce cracking of the glass during processes that involve heating and cooling of the assemblies. An example of an electronic system using assemblies with system level packaging as described in the present disclosure is included to show an example of a higher level device application.

FIG. 6 illustrates a system level diagram, according to one embodiment of the present disclosure. For instance, FIG. 6 depicts an example of a system that can include an electronic device packaged with a substrate having a glass core layer. The glass core layer can include TGVs with a stress-relieving via liner. In one embodiment, system 600 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance, or any other type of computing device. In some embodiments, system 600 is a system on a chip (SOC) system. In one example, two or more systems as shown in FIG. 6 may be provided circuit power using components attached to a back side of a package substrate as described in the present disclosure.

In one embodiment, processor 610 has one or more processing cores 612 and 612N, where N is a positive integer and 612N represents the Nth processor core inside processor 610. In one embodiment, system 600 includes multiple processors including 610 and 605, where processor 605 has logic similar or identical to the logic of processor 610. In some embodiments, processing core 612 includes, but is not limited to, pre-fetch logic to fetch instructions, decode logic to decode the instructions, execution logic to execute instructions and the like. In some embodiments, processor 610 has a cache memory 616 to cache instructions and/or data for system 600. Cache memory 616 may be organized into a hierarchal structure including one or more levels of cache memory.

In some embodiments, processor 610 includes a memory controller 614, which is operable to perform functions that enable the processor 610 to access and communicate with memory 630 that includes a volatile memory 632 and/or a non-volatile memory 634. In some embodiments, processor 610 is coupled with memory 630 and chipset 620. Processor 610 may also be coupled to a wireless antenna 678 to communicate with any device configured to transmit and/or receive wireless signals. In one embodiment, the wireless antenna interface 678 operates in accordance with, but is not limited to, the IEEE 802.11 standard and its related family, Home Plug AV (HPAV), Ultra-Wide Band (UWB), Bluetooth, WiMax, or any form of wireless communication protocol.

In some embodiments, volatile memory 632 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 634 includes, but is not limited to, flash memory, phase change memory (PCM), read-only memory (ROM), electrically erasable programmable read-only memory (EEPROM), or any other type of non-volatile memory device.

Memory 630 stores information and instructions to be executed by processor 610. In one embodiment, memory 630 may also store temporary variables or other intermediate information while processor 610 is executing instructions. In the illustrated embodiment, chipset 620 connects with processor 610 via Point-to-Point (PtP or P-P) interfaces 617 and 622. Chipset 620 enables processor 610 to connect to other elements in system 600. In some embodiments, interfaces 617 and 622 operate in accordance with a PtP communication protocol such as the Intel® QuickPath Interconnect (QPI) or the like. In other embodiments, a different interconnect may be used.

In some embodiments, chipset 620 is operable to communicate with processor 610, 605N, display device 640, and other devices 672, 676, 674, 660, 662, 664, 666, 677, etc. Buses 650 and 655 may be interconnected together via a bus bridge 672. Chipset 620 connects to one or more buses 650 and 655 that interconnect various elements 674, 660, 662, 664, and 666. Chipset 620 may also be coupled to a wireless antenna 678 to communicate with any device configured to transmit and/or receive wireless signals. Chipset 620 connects to display device 640 via interface (I/F) 626. Display 640 may be, for example, a touchscreen, a liquid crystal display (LCD), a plasma display, cathode ray tube (CRT) display, or any other form of visual display device. In some embodiments, processor 610 and chipset 620 are merged into a single SOC. In one embodiment, chipset 620 couples with (e.g., via interface 624) a non-volatile memory 660, a mass storage medium 662, a keyboard/mouse 664, and a network interface 666 via I/F 624 and/or I/F 626, I/O devices 674, smart TV 676, consumer electronics 677 (e.g., PDA, Smart Phone, Tablet, etc.).

In one embodiment, mass storage medium 662 includes, but is not limited to, a solid state drive, a hard disk drive, a universal serial bus flash memory drive, or any other form of computer data storage medium. In one embodiment, network interface 666 is implemented by any type of well-known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra-Wide Band (UWB), Bluetooth, WiMax, or any form of wireless communication protocol.

While the modules shown in FIG. 6 are depicted as separate blocks within the system 600, the functions performed by some of these blocks may be integrated within a single semiconductor circuit or may be implemented using two or more separate integrated circuits. For example, although cache memory 616 is depicted as a separate block within processor 610, cache memory 616 (or selected aspects of 616) can be incorporated into processor core 612.

The devices, systems, and methods described can provide improved routing of power and reduced size of a multichip package by providing high magnetic permeability components for the circuits that produce the power with the substrate.

To better illustrate the method and apparatuses disclosed herein, a non-limiting list of example embodiments is provided here:

Example 1 includes subject matter (such as a substrate for an electronic system) comprising a glass core layer including a first surface and a second surface opposite the first surface, and at least one through-glass via (TGV) extending through the glass core layer from the first surface to the second surface. The TGV includes an opening filled with an electrically conductive material, and a via liner including a sidewall material disposed on a sidewall of the opening between the glass of the glass core layer and the electrically conductive material, wherein the sidewall material includes carbon.

In Example 2, the subject matter of Example 1 optionally includes a sidewall material comprising parylene.

In Example 3, the subject matter of one or both of Examples 1 and 2 optionally includes a sidewall material with a modulus in a range of 70-690 MegaPascals (MPa).

In Example 4, the subject matter of one or any combination of Examples 1-3 optionally includes a first surface buffer layer of the sidewall material disposed on the first surface of the glass core layer, a second surface buffer layer of the sidewall material disposed on the second surface of the glass core layer, and a via liner that extends from the first surface buffer layer to the second surface buffer layer.

In Example 5, the subject matter of Example 4 optionally includes the electrically conductive material of the TGV extending through the first surface buffer layer, and a width of the electrically conductive material in the first surface buffer layer is the same as a width of the electrically conductive material within the TGV below the first surface buffer layer.

In Example 6, the subject matter of one or both of Examples 4 and 5 optionally includes a first buildup layer contacting the first surface buffer layer and a second buildup layer contacting the second surface buffer layer, wherein the first and second buildup layers include electrically conductive interconnect contacting the at least one TGV.

In Example 7, the subject matter of Example 6 optionally includes a multi-die interconnect bridge (MIB) disposed in the first buildup layer, and the electrically conductive interconnect of the first buildup layer provides electrical continuity between the at least one TGV and the MIB.

In Example 8, the subject matter of Example 7 optionally includes at least one bonding pad on a first surface of the substrate. The MIB and the electrically conductive interconnect of the first buildup layer provide electrical continuity between the at least one TGV and the at least one bonding pad.

Example 9 includes subject matter (such as a method of making a substrate for an electronic system) or can optionally be combined with one or any combination of Examples 1-8 to include such subject matter, comprising forming at least one opening for at least one through glass via (TGV) in a glass core layer of the substrate, the at least one opening extending from a first surface of the glass core layer to a second surface of the glass core layer, disposing a sidewall material on a sidewall of the at least one opening to form a via liner, and filling the at least one opening with electrically conductive material with the via liner between the glass of the glass core layer and the electrically conductive material.

In Example 10, the subject matter of Example 9 optionally includes disposing parylene on the sidewall of the at least one opening.

In Example 11, the subject matter of one or both of Examples 9 and 10 optionally includes disposing a sidewall material having a modulus in a range of 70-690 MegaPascals (MPa) on the sidewall of the at least one opening.

In Example 12, the subject matter of one or any combination of Examples 9-11 optionally includes disposing the sidewall material on the first surface of the glass core layer to form a first surface buffer layer on the glass core layer, and disposing the sidewall material on a second surface of the glass core layer to form a second surface buffer layer on the glass core layer.

In Example 13, the subject matter of Example 12 optionally includes disposing the sidewall material on the first surface of the glass core layer and in the opening of the glass core layer to form an opening in the first surface buffer layer having a same width as an opening of the via line.

In Example 14, the subject matter of one or both of Examples 12 and 13 optionally includes forming a first buildup layer on the first surface buffer layer and a second buildup layer on the second surface buffer layer, wherein the first and second buildup layers include electrically conductive interconnect, and contacting the at least one TGV to the electrically conductive interconnect of the first and second buildup layers.

In Example 15, the subject matter of Example 14 optionally includes disposing a multi-die interconnect bridge (MIB) disposed in the first buildup layer, wherein the MIB includes electrically conductive interconnect, and electrically connecting the MIB to the at least one TGV using the electrically conductive interconnect of the first buildup layer.

Example 16 includes subject matter (such as an electronic system) or can optionally by combined with one or any combination of Examples 1-16 to include such subject matter, comprising a substrate and an integrated circuit (IC) die. The substrate includes a glass core layer including at least one through-glass via (TGV) extending through the glass core layer, the TGV including an electrically conductive material and a via liner of a sidewall material disposed on a sidewall of TGV between the glass of the glass core layer and the electrically conductive material; and a first buildup layer on a first surface of the glass core layer and including electrically conductive interconnect. The IC die is attached to the first buildup layer and has at least one bonding pad. The electrically conductive interconnect of the first buildup layer electrically connects the at least one bonding pad of the IC die to the at least one TGV.

In Example 17, the subject matter of Example 16 optionally includes a second buildup layer on a second surface of the glass core layer and including electrically conductive interconnect, and at least one discrete passive component attached to the second buildup layer and electrically connected to the at least one TGV by the electrically conductive interconnect of the second buildup layer.

In Example 18, the subject matter of one or both of Examples 16 and 17 optionally includes a sidewall material having a modulus in a range of 70-690 MegaPascals (MPa).

In Example 19, the subject matter of one or any combination of Examples 16-18 optionally includes a first surface buffer layer of the sidewall material disposed on the first surface of the glass core layer and contacting the via liner.

In Example 20, the subject matter of one or any combination of Examples 16-19 optionally includes a multi-die interconnect bridge (MIB) disposed in the first buildup layer. The MIB and the electrically conductive interconnect of the first buildup layer provide electrical continuity between the at least one TGV and the IC die.

These non-limiting example embodiments can be combined in any permutation or combination. Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

Although an overview of the inventive subject matter has been described with reference to specific example embodiments, various modifications and changes may be made to these embodiments without departing from the broader scope of embodiments of the present disclosure.

The embodiments illustrated herein are described in sufficient detail to enable those skilled in the art to practice the teachings disclosed. Other embodiments may be used and derived therefrom, such that structural and logical substitutions and changes may be made without departing from the scope of this disclosure. The Detailed Description, therefore, is not to be taken in a limiting sense, and the scope of various embodiments is defined only by the appended claims, along with the full range of equivalents to which such claims are entitled.

As used herein, the term “or” may be construed in either an inclusive or exclusive sense. Moreover, plural instances may be provided for resources, operations, or structures described herein as a single instance. Additionally, boundaries between various resources, operations, modules, engines, and data stores are somewhat arbitrary, and particular operations are illustrated in a context of specific illustrative configurations. Other allocations of functionality are envisioned and may fall within a scope of various embodiments of the present disclosure. In general, structures and functionality presented as separate resources in the example configurations may be implemented as a combined structure or resource. Similarly, structures and functionality presented as a single resource may be implemented as separate resources. These and other variations, modifications, additions, and improvements fall within a scope of embodiments of the present disclosure as represented by the appended claims. The specification and drawings are, accordingly, to be regarded in an illustrative rather than a restrictive sense.

It will also be understood that, although the terms “first,” “second,” and so forth may be used herein to describe various elements, these elements should not be limited by these terms. These terms are only used to distinguish one element from another. For example, a first contact could be termed a second contact, and, similarly, a second contact could be termed a first contact, without departing from the scope of the present example embodiments. The first contact and the second contact are both contacts, but they are not the same contact.

The terminology used in the description of the example embodiments herein is for the purpose of describing particular example embodiments only and is not intended to be limiting. As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

What is claimed is:

1. A substrate for an electronic system, the substrate comprising:
a glass core layer including:
a first surface and a second surface opposite the first surface; and
at least one through-glass via (TGV) extending through the glass core layer from the first surface to the second surface, the TGV including:
an opening filled with an electrically conductive material; and
a via liner including a sidewall material disposed on a sidewall of the opening between the glass of the glass core layer and the electrically conductive material, wherein the sidewall material includes carbon.

2. The substrate of claim 1, wherein the sidewall material comprises parylene.

3. The substrate of claim 1, wherein a modulus of the sidewall material is in a range of 70-690 MegaPascals (MPa).

4. The substrate of claim 1, including:
a first surface buffer layer of the sidewall material disposed on the first surface of the glass core layer;
a second surface buffer layer of the sidewall material disposed on the second surface of the glass core layer; and
wherein the via liner extends from the first surface buffer layer to the second surface buffer layer.

5. The substrate of claim 4, wherein the electrically conductive material of the TGV extends through the first surface buffer layer, and a width of the electrically conductive material in the first surface buffer layer is the same as a width of the electrically conductive material within the TGV below the first surface buffer layer.

6. The substrate of claim 4, including a first buildup layer contacting the first surface buffer layer and a second r buildup layer contacting the second surface buffer layer, wherein the first and second buildup layers include electrically conductive interconnect contacting the at least one TGV.

7. The substrate of claim 6, including a multi-die interconnect bridge (MIB) disposed in the first buildup layer, and the electrically conductive interconnect of the first buildup layer provides electrical continuity between the at least one TGV and the MIB.

8. The substrate of claim 7, including:
at least one bonding pad on a first surface of the substrate; and
wherein the MIB and the electrically conductive interconnect of the first buildup layer provide electrical continuity between the at least one TGV and the at least one bonding pad.

9. A method of making a substrate for an electronic system, the method comprising:
forming at least one opening for at least one through glass via (TGV) in a glass core layer of the substrate, the at least one opening extending from a first surface of the glass core layer to a second surface of the glass core layer;
disposing a sidewall material on a sidewall of the at least one opening to form a via liner; and
filling the at least one opening with electrically conductive material with the via liner between the glass of the glass core layer and the electrically conductive material.

10. The method of claim 9, wherein the disposing the sidewall material includes disposing parylene on the sidewall of the at least one opening.

11. The method of claim 9, wherein the disposing the sidewall material includes disposing a sidewall material having a modulus in a range of 70-690 MegaPascals (MPa) on the sidewall of the at least one opening.

12. The method of claim 9, wherein the disposing the sidewall material includes:
disposing the sidewall material on the first surface of the glass core layer to form a first surface buffer layer on the glass core layer; and
disposing the sidewall material on a second surface of the glass core layer to form a second surface buffer layer on the glass core layer.

13. The method of claim 12, wherein the disposing the sidewall material includes disposing the sidewall material on the first surface of the glass core layer and in the opening of the glass core layer to form an opening in the first surface buffer layer having a same width as an opening of the via liner.

14. The method of claim 12, including:
forming a first buildup layer on the first surface buffer layer and a second buildup layer on the second surface buffer layer, wherein the first and second buildup layers include electrically conductive interconnect; and
contacting the at least one TGV to the electrically conductive interconnect of the first and second buildup layers.

15. The method of claim 14, including:
disposing a multi-die interconnect bridge (MIB) disposed in the first buildup layer, wherein the MIB includes electrically conductive interconnect; and
electrically connecting the MIB to the at least one TGV using the electrically conductive interconnect of the first buildup layer.

16. An electronic system, the system comprising:
a substrate including:
a glass core layer including at least one through-glass via (TGV) extending through the glass core layer, the TGV including an electrically conductive material and a via liner of a sidewall material disposed on a sidewall of TGV between the glass of the glass core layer and the electrically conductive material; and
a first buildup layer on a first surface of the glass core layer and including electrically conductive interconnect; and
an integrated circuit (IC) die attached to the first buildup layer and having at least one bonding pad; and
wherein the electrically conductive interconnect of the first buildup layer electrically connects the at least one bonding pad of the IC die to the at least one TGV.

17. The system of claim 16, including:
a second buildup layer on a second surface of the glass core layer and including electrically conductive interconnect; and
at least one discrete passive component attached to the second buildup layer and electrically connected to the at least one TGV by the electrically conductive interconnect of the second buildup layer.

18. The system of claim 16, wherein a modulus of the sidewall material is in a range of 70-690 MegaPascals (MPa).

19. The system of claim 16, including a first surface buffer layer of the sidewall material disposed on the first surface of the glass core layer and contacting the via liner.

20. The system of claim 16, including:
a multi-die interconnect bridge (MIB) disposed in the first buildup layer; and
wherein the MIB and the electrically conductive interconnect of the first buildup layer provide electrical continuity between the at least one TGV and the IC die.
